(19) United States
(12) Patent Application Publication
(10) Pub. No.: US 2024/0074031 A1
(43) Pub. Date: Feb. 29, 2024

(54) TEXTURED METAL CORE PRINTED CIRCUIT BOARDS FOR IMPROVED THERMAL DISSIPATION

(71) Applicant: CreeLED, Inc., Durham, NC (US)

(72) Inventor: Everett Bradford, Apex, NC (US)

(21) Appl. No.: 17/897,617

(22) Filed: Aug. 29, 2022

(51) Int. Cl. H05K 1/02; H05K 1/05; H05K 1/18

(52) U.S. Cl. CPC H05K 1/021; H05K 1/0272; H05K 1/05; H05K 1/181; H05K 2201/0338; H05K 2201/064; H05K 2201/066; H05K 2201/10106

(57) ABSTRACT

The present disclosure relates to a textured metal core printed circuit board (MCPCB) that has improved thermal dissipation characteristics to remove thermal energy generated by solid-state lighting devices including light-emitting diodes (LEDs) and other electronic components. The textured MCPCB surface can increase the surface area of the MCPCB surface in order to more effectively radiate or conduct thermal energy to the surroundings. In one embodiment, the textured surface of the MCPCB can be exposed to the air without the need for a separate heatsink component. The textured MCPCB surface can machined to form grooves on the surface of the MCPCB in order to channel air and increase the surface area. In an embodiment, the textured MCPCB surface can be etched to increase the surface area of the textured MCPCB surface on a microscopic scale and to induce turbulent air patterns which can improve the dissipation of thermal energy.

### FIELD OF THE DISCLOSURE

The present disclosure relates to metal core printed circuit boards, and more particularly to textured metal core printed circuit boards that can more effectively dissipate thermal energy.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

In high-powered LED lighting (and other high powered electronics) components are often mounted to a metal core printed circuit board (MCPCB). The MCPCB has a metal core (often aluminum or copper) instead of the traditional Fiberglass which makes it thermally conductive allowing the MCPCB to more efficiently remove heat from the components. The MCPCB is used as an interface between the heat producing electrical components and a separate heatsink or pipe which dissipates the thermal energy to the surrounding air or a fluid.

As advancements in modern LED technology and high powered electronics progress, the art continues to seek improved thermal dissipation characteristics capable of overcoming challenges associated with conventional devices.

### SUMMARY

The present disclosure relates to a textured metal core printed circuit board (MCPCB) that has improved thermal dissipation characteristics to remove thermal energy generated by solid-state lighting devices including light-emitting diodes (LEDs) and other electronic components. The textured MCPCB surface can increase the surface area of the MCPCB surface in order to more effectively radiate or conduct thermal energy to the surroundings. In one embodiment, the textured surface of the MCPCB can be exposed to the air without the need for a separate heatsink component. The textured MCPCB surface can machined to form grooves on the surface of the MCPCB in order to channel air and increase the surface area. In an embodiment, the textured MCPCB surface can also be etched to increase the surface area of the textured MCPCB surface on a microscopic scale and to induce turbulent air patterns which can more effectively transfer thermal energy away from the MCPCB.

In an embodiment of the present disclosure, an MCPCB can include a copper layer with one or more circuit components mounted on a first surface thereof. The MCPCB can also include a dielectric layer bonded to a second surface of the copper layer, opposite the first surface. The MCPCB can also include an aluminum layer bonded to the dielectric layer, wherein a first surface of the aluminum layer is bonded to the dielectric layer, and a second surface of the aluminum, opposite the first surface, is textured, resulting in an increased surface area relative to an untextured surface.

In another embodiment of the present disclosure, an assembly can include a MCPCB that has a copper layer with one or more circuit components mounted on a first surface thereof, a dielectric layer bonded to a second surface of the copper layer, opposite the first surface, and an aluminum layer bonded to the dielectric layer, wherein a first surface of the aluminum layer is bonded to the dielectric layer, and a second surface of the aluminum, opposite the first surface, is textured, resulting in an increased surface area relative to an untextured surface. The assembly can also include a housing, mounted to the metal core printed circuit board, and at least partially covering the first surface of the copper layer.

In another embodiment of the present disclosure, a light emitting diode device can include a light emitting diode chip. The light emitting diode device can also include a metal core printed circuit board on which the light emitting diode chip is mounted on a top surface thereof, wherein a bottom surface of the metal core printed circuit board is textured with one or more of grooves or etching. The light emitting diode device can also include a housing, mounted to the metal core printed circuit board, and at least partially covering the top surface of the metal core printed circuit board, wherein the housing does not cover the bottom surface of the metal core printed circuit board.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary embodiment of a metal core printed circuit board according to one or more aspects of the present disclosure.

FIG. 2A illustrates a view of a textured metal core printed circuit board according to one or more aspects of the present disclosure.

FIG. 2B illustrates another view of a textured metal core printed circuit board according to one or more aspects of the present disclosure.

FIGS. 3A, 3B, 3C, and 3D illustrate exemplary embodiments of textured metal core printed circuit boards with different groove patterns according to one or more aspects of the present disclosure.

FIG. 4 illustrates an exemplary embodiment of a textured metal core printed circuit board according to one or more aspects of the present disclosure.

FIG. 5 illustrates an exemplary embodiment of a textured metal core printed circuit board in an assembly according to one or more aspects of the present disclosure.

FIG. 6 illustrates an exemplary embodiment of a textured metal core printed circuit board with heatsink like vanes according to one or more aspects of the present disclosure.

FIGS. 7A and 7B illustrate an exemplary embodiment of a textured metal core printed circuit board mounted to a heatsink according to one or more aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a textured metal core printed circuit board (MCPCB) that has improved thermal dissipation characteristics to remove thermal energy generated by solid-state lighting devices including light-emitting diodes (LEDs) and other electronic components. The textured MCPCB surface can increase the surface area of the MCPCB surface in order to more effectively radiate or conduct thermal energy to the surroundings. In one embodiment the textured surface of the MCPCB can be exposed to the air, without the need for a separate heatsink component. The textured MCPCB surface can machined to form grooves on the surface of the MCPCB in order to channel air and increase the surface area. In an embodiment, the textured MCPCB surface can also be etched to increase the surface area of the textured MCPCB surface on a microscopic scale, and to induce turbulent air patterns which can more effectively transfer thermal energy away from the MCPCB.

In high-powered LED lighting (and other high-power electronics), components are often mounted to the MCPCB. This board has a metal core (often aluminum or copper) instead of the typical fiberglass (FR-4) PCB material, which makes it thermally conductive, allowing the PCB to remove heat from the components. In most applications, this MCPCB is an interface between the heat-producing components and a separate heatsink or heat pipe which dissipates the heat to the surrounding air (or other fluid). The heatsink would typically be a metal shape with fins, pins, or other structure that increases surface area, which allows it to transfer the heat to the air. The present disclosure provides a means to remove the interface between the MCPCB and the heatsink by combining the two components into one. By designing the back side of a single-sided MCPCB to have a texture that increases the surface area, the MCPCB can directly become the device which transfers heat to the air or other fluid, reducing complexity and increasing efficiency of thermal energy dissipation by removing interfaces.

In various embodiments, the texturing of the MCPCB back side can be at a range of size scales, with a tradeoff between manufacturing complexity and heat transfer capability. As used herein, a textured surface and/or texturing may refer to any nonplanar surface or nonplanar features, including, grooves, ridges, pillars, and repeating features or patterns that are machined or etched into a surface of a metal layer of the MCPCB in order to increase the surface area of the MCPCB or to roughen the surface thereof. The back of the MCPCB can be textured on a millimeter scale to increase the surface area by machining or extruding continuous ridges in the surface, which is a simple and inexpensive manufacturing option. More complex patterns and textures could be accomplished by more complex processes such as etching (creating texture on a smaller scale), or Computer Numerical Control (CNC) machining complex patterns such as pillars or grids, which might be useful for mechanical reasons in addition to heat transfer. Machined macro-scale features could also be combined with etched micro-scale textures.

In an embodiment, in addition to direct heat transfer to air, the textured MCPCB can also be used to improve the effectiveness of a traditional thermal interface to a heatsink. Thermal interfaces such as grease or silicone pads will conform to fill microscopic features in the PCB material, increasing the surface area of the interface and thereby improve the thermal conductivity to the heatsink.

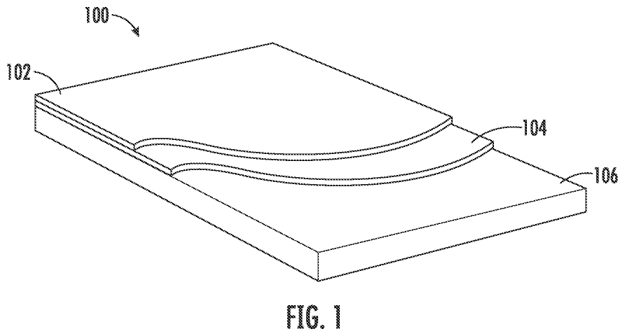

FIG. 1 illustrates an exemplary embodiment of a MCPCB 100 according to one or more aspects of the present disclosure. In an embodiment. MCPCB 100 can include a first metal layer 102 that is copper, a dielectric 104, and a second metal layer of aluminum 106. In various embodiments, the first metal layer 102 can be copper, and the second metal layer 106 can be aluminum, although in other embodiments, other combinations of metals and/or alloys are possible, including copper. For example, in some embodiments, a copper core PCB can have both first and second metal layers be made of copper or a copper alloy.

In an embodiment, the dielectric layer 104 can be electrically insulating so that little or no current passes between the metal layers 102 and 106, while being thermally conductive, allowing thermal energy to transfer between layers.

In an embodiment, the layers can be bonded to each other with an adhesive, and in other embodiments, the layers can be formed via deposition.

In an embodiment, the first metal layer 102 can have a thickness of between 20-400 microns, the dielectric layer 104 can be between 75 and 200 microns, while the second metal layer 106 can be between 0.5-5 mm.

In an embodiment, the MCPCB can have a solder mask on the top surface on the first metal layer on which one or more electrical circuit components can be placed.

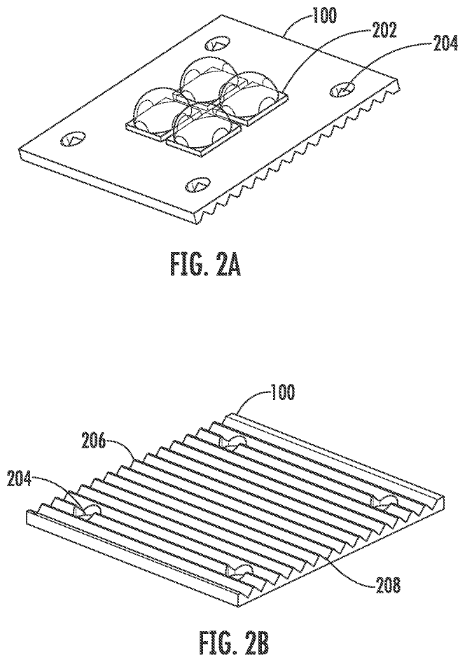

FIGS. 2A and 2B illustrate views of a textured MCPCB 100 according to one or more aspects of the present disclosure. FIG. 2A shows the top (or first side) of the MCPCB 100, and FIG. 2B shows the bottom (or second side) of the MCPCB 100.

On the top surface one or more circuit component 202 can be mounted on the top of the MCPCB 100. The circuit components 202 can include any type of circuit components that generate heat, and may be susceptible, in either performance or longevity to increased temperatures. In at least an embodiment depicted in FIG. 2A, the circuit components 202 can be LED chips that generate light, and as a byproduct generate thermal energy. Traditionally, the MCPCB 100 would be bonded or otherwise thermally coupled to a heatsink device which can dissipate the heat or thermal energy by conduction and/or radiation. In one or more embodiments of the present disclosure however, the MCPCB 100 itself can have grooves, ridges or other texturing and patterning formed thereon, on an opposite side of the metal core of the second metal layer 106 that is bonded to the dielectric 104. The grooves, ridges or other texturing and patterning can increase the surface area of the second metal layer 106 to increase the ability of the second metal layer 106 to dissipate heat to the surroundings. The increased surface area can increase the area from which the second metal layer 106 radiates the thermal energy, and also increase the area for conduction to the air.

In an embodiment, the back side of the MCPCB 100 that is textured can be exposed to the air or in another embodiment, exposed to a fluid that can serve to carry the thermal energy away from the MCPCB 100.

In an embodiment, the first metal layer 102 of FIG. 1 can have a solder mask applied over the first metal layer 102 for protection against oxidation and to prevent solder bridges from forming between closely spaced solder pads. A solder bridge is an unintended electrical connection between two conductors by means of a small blob of solder. PCBs use solder masks to prevent this from happening. In an embodiment, the solder mask can be in between the circuit component 202 and the top surface of the MCPCB 100 (e.g., first metal layer 102).

In an embodiment, the MCPCB 100 can have holes 204 formed in the MCPCB 100 in order to enable the MCPCB 100 to be mounted via screws or fasteners to a housing, a heatsink, or some other assembly or device. In an embodiment, the holes 204 can be threaded. In an embodiment, the holes 204 can be embossed to provide a raised surface around the top side or bottom side of the holes 204 to provide a surface on which the MCPCB 100 can abut the apparatus being fastened thereon, without damaging the top surface of the MCPCB 100 or the texturing/patterning on the back surface of the MCPCB 100.

In an embodiment, an application in which the MCPCB 100 could be used could include LED boards of moderate power levels. While the MCPCB 100 has more surface area than a traditional MCPCB, it may still have a lower surface area relative to standard heatsinks which means that the MCPCB 100 is more likely to be used at lower (or more spread out) power levels and more likely to be used with forced-air convection (fan cooled), but could still be applied to natural convection and higher power levels in various embodiments. LED boards using this technique could be used in light fixtures of various types (linear, panel, downlight) but it is most applicable to those with large surface areas and those where the design can easily incorporate an LED board that can be exposed to the air. Designs using this technique could be made to expose the back of the MCPCB as a part of the entire product's outer surface, or it might be enclosed with an air gap to allow air to travel through a channel inside the fixture. The MCPCB 100 could also be used in other non-LED high-power electronics such as semiconductors used in power supplies. This technique might be used for liquid-cooled applications by putting the back side of the MCPCB 100 in contact with a flowing coolant such as water.

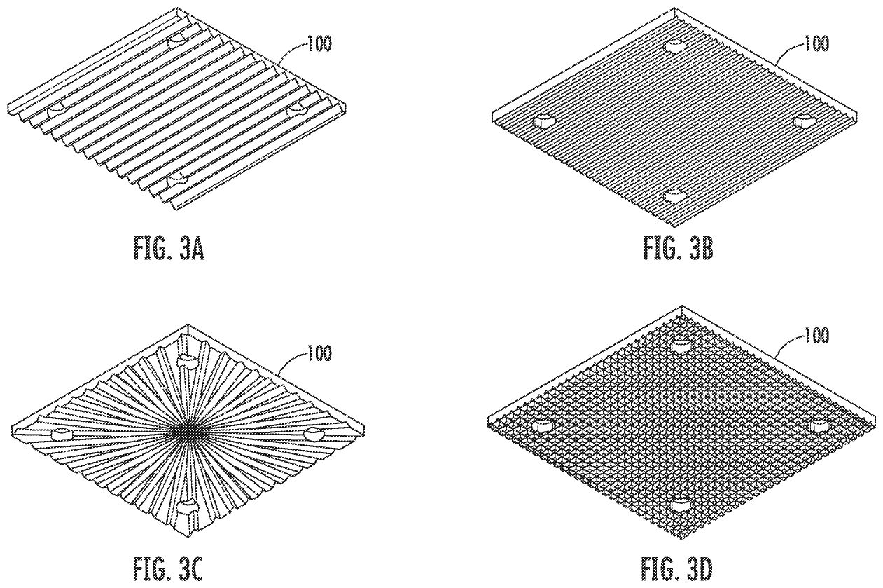

In an embodiment, as shown in FIG. 2B, the texturing/patterning on the back surface of the MCPCB 100 can include ridges 206 and/or grooves 208 that are machined into the second metal layer 106. In the embodiment shown here in FIG. 2B, the grooves 208 or ridges 206 are parallel to each other across the surface of the MCPCB 100, but in other embodiments (See e.g., FIGS. 3A-3D) other designs are possible.

FIGS. 3A, 3B, 3C, and 3D illustrate exemplary embodiments of textured metal core printed circuit boards with different groove patterns according to one or more aspects of the present disclosure.

The texturing/patterning of the back side of the MCPCB 100 can be at a range of sizes/scales, with a tradeoff between manufacturing complexity and heat transfer capability. The back of the MCPCB can be textured on a millimeter scale to increase the surface area by machining or extruding continuous ridges (e.g., ridges 206 in FIG. 2A) in the surface, which can be the simplest and cheapest manufacturing option. More complex patterns and textures could be accomplished by more complex processes such as etching (creating texture on a smaller scale), or CNC machining complex patterns such as pillars or grids, which might be useful for mechanical reasons in addition to heat transfer. Machined macro-scale features could also be combined with etched micro-scale textures.

In an embodiment, as shown in FIG. 3A, parallel ridges and grooves can be formed, similar to FIG. 3B, but in FIG. 3B, the depth and width of the ridges can be smaller than in FIG. 3A. Deeper grooves and/or higher ridges can be formed depending on the heat dissipation requirements of the MCPCB, with higher ridges, deeper grooves facilitating increased heat dissipation due to the larger surface area. In other embodiments, smaller grooves/ridges can be formed if the heat dissipation requirements are reduced, or if there is a greater need for structural integrity, or to reduce the machining costs.

Parallel ridges/grooves as in FIGS. 3A and 3B can facilitate improved air circulation if there is forced air in a direction parallel to the ridges/grooves. In other embodiments, such as in FIG. 3C, with radial grooves that intersect along a central portion of the MCPCB 100 and extend toward peripheral edges of the MCPCB 100, the air can be flowing in a direction orthogonal to the surface of the MCPCB, and the air can be directed towards the outer portion of the MCPCB. In some embodiments, the ridges/grooves could be in a spiral pattern.

In other embodiments, such as in FIG. 3D, the grooves can form a crosshatching, or honeycomb structure, which can cause increased air turbulence leading to greater convection of thermal energy away from the MCPCB, while also improving the structural integrity or mechanical rigidity.

Etching, media blasting, or other processes could be used to texture the material on a microscopic scale, which could produce regular patterns or random/non-repeating features. These techniques could be used alone or in combination with the machining processes mentioned above, and would also serve to increase air turbulence, leading to greater heat or thermal energy dissipation.

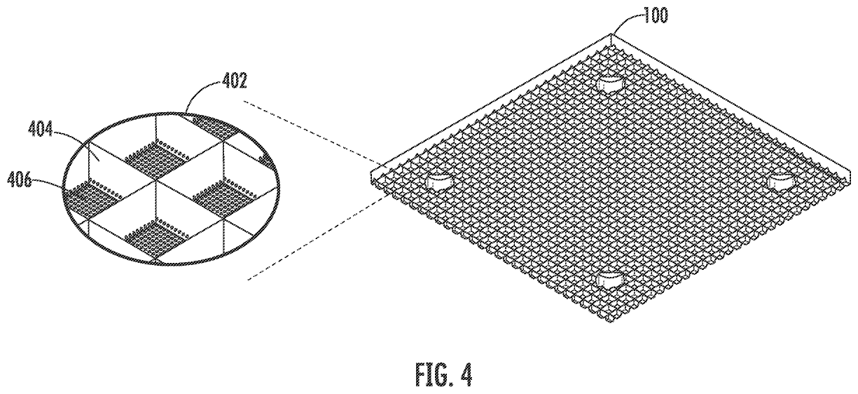

FIG. 4 illustrate an exemplary embodiment of a textured metal core printed circuit board according to one or more aspects of the present disclosure. The embodiment in FIG. 4 illustrates an example described above where a MCPCB 100 can be machined or cut such that, as shown in the expanded view 402, there can be a cross hatch pattern with walls 404 surrounding open areas, where the surface in the open areas can be etched or media-blasted with microtexturing 406 to further increase the surface area of the MCPCB 100.

In an embodiment, the MCPCB 100 can thus be textured with a plurality of patterns. For example, a first predefined pattern can include the walls 404 formed onto the MCPCB 100, and then the second predefined pattern can include the microtexturing 406 formed in between the features of the first predefined pattern. The first predefined pattern can include features with larger heights, depths, spacings, etc., relative to the second predefined pattern.

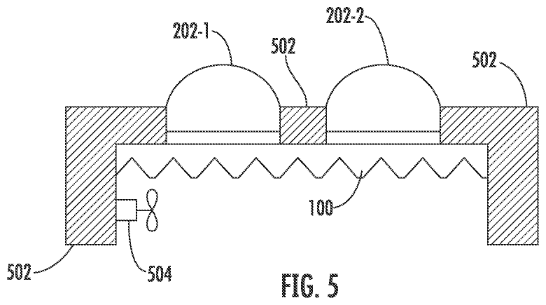

FIG. 5 illustrates an exemplary embodiment of a textured metal core printed circuit board in an assembly according to one or more aspects of the present disclosure. In an embodiment, the assembly 502 can be part of a housing of a lighting fixture, part of a housing of an intermediate lighting module or lighting panel that can then be assembled in a lighting fixture.

In an embodiment, the MCPCB 100 can have LED chips 202-1 and 202-2 on the top surface of MCPCB 100, and an assembly 502 can be mounted to the MCPCB 100 (e.g., via the fastening holes 204). The assembly 502 can in an embodiment cover the top surface of the MCPCB 100 except for openings where the LED chips 202-1 and 202-2 can protrude through so that their light is visible. In an embodiment, the assembly 502 can be formed such that the back of the MCPCB 100 is exposed to the outside as shown in FIG. 5. In other embodiments, the assembly can also cover the back of the MCPCB 100 while still allowing the textured back of the MCPCB 100 to be exposed to the air internally in order to dissipate thermal energy. The assembly 502 can include vents or openings in order to exchange air so that the MCPCB 100 can be continuously cooled.

In an embodiment, a fan 504 or other type of forced air circulator can be optionally mounted to the assembly or some other surface to facilitate improved circulation of the air and this improve the ability of the MCPCB 100 to dissipate heat. In an embodiment, the position of the fan 504 can be adjusted based on the texture pattern of the MCPCB 100 in order to improve convection. For example, the fan can be placed such that the air flow direction is parallel to the grooves when the grooves are in parallel lines. If the grooves are in a radial or spiral pattern, the fan can be placed such that an air flow direction is orthogonal to the surface of the MCPCB 100.

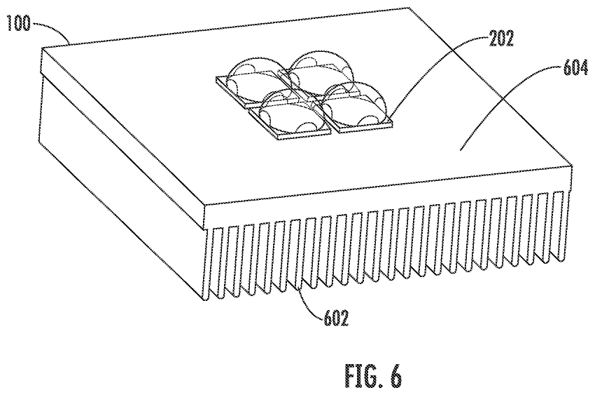

FIG. 6 illustrate an embodiment of a textured metal core printed circuit board 100 with heatsink like vanes according to one or more aspects of the present disclosure. In an embodiment, the dielectric layer 104 and the first metal layer 102, and solder mask and circuit components 202 of FIGS. 1 and 2A can be formed on top of an aluminum base 604 that is already shaped in to a heatsink like shape with vanes 602. In an embodiment, the vanes 602 can be machined after the MCPCB 100 is formed. This embodiment can have thermal dissipation improvements over other designs disclosed here, but might be more difficult to machine, or produce as a new PCB process might be used to produce such an embodiment.

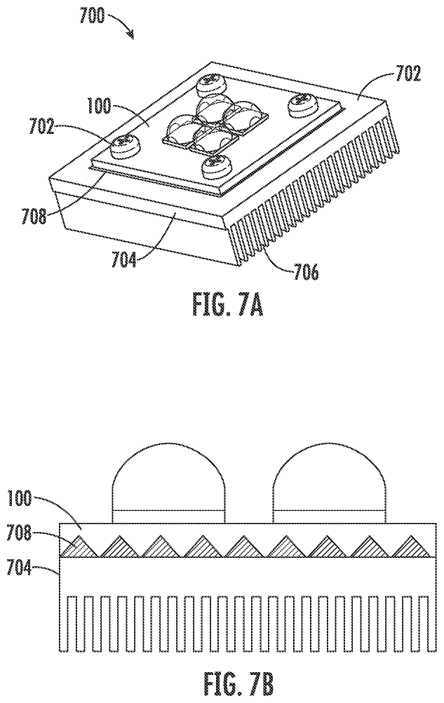

FIGS. 7A and 7B illustrate an embodiment, where a MCPCB 100 can be textured as described in the present disclosure, but can be mounted on a heatsink base 704 via fasteners 702. A thermal paste 708 or other thermally conductive compound can be on the surface of the heatsink base 704 and facilitate heat transfer or thermal energy transfer from the MCPCB 100 to the heatsink base 704, where the thermal energy can then be dissipated by heatsink vanes 706. The increased surface area of the textured MCPCB 100 can increase the surface area in which the thermal paste 708 is in contact, thus improving the heat transfer in this traditional use of a heatsink and MCPCB.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A metal core printed circuit board, comprising:
a first metal layer with one or more circuit components mounted on a first surface thereof;
a dielectric layer bonded to a second surface of the first metal layer, opposite the first surface; and
a second metal layer bonded to the dielectric layer, wherein a first surface of the second metal layer is bonded to the dielectric layer, and a second surface of the second metal layer, opposite the first surface, is textured.

2. The metal core printed circuit board of claim 1, wherein the second metal layer is exposed to air.

3. The metal core printed circuit board of claim 1, wherein the textured second surface of the second metal layer facilitates improved thermal energy transfer to a heat sink.

4. The metal core printed circuit board of claim 1, wherein the second surface of the second metal layer is grooved according to a predefined pattern.

5. The metal core printed circuit board of claim 4, wherein the predefined pattern is at least one of a radial pattern, a parallel groove pattern, a cross-hatch pattern, or a spiral pattern.

6. The metal core printed circuit board of claim 4, wherein the predefined pattern comprises a first predefined pattern and a second predefined pattern that is arranged between individual features of the first predefined pattern.

7. The metal core printed circuit board of claim 1, wherein the second surface of the second metal layer is etched.

8. The metal core printed circuit board of claim 1, wherein the first metal layer is copper and the second metal layer is at least one of copper or aluminum.

9. An assembly, comprising:
a metal core printed circuit board comprising:
a first metal layer with one or more circuit components mounted on a first surface thereof;
a dielectric layer bonded to a second surface of the first metal layer, opposite the first surface; and
a second metal layer bonded to the dielectric layer, wherein
a first surface of the second metal layer is bonded to the dielectric layer, and a second surface of the second metal layer, opposite the first surface, is textured, and
a housing, mounted to the metal core printed circuit board, and at least partially covering the first surface of the first metal layer.

10. The assembly of claim 9, further comprising:
a fan configured to blow air over the second surface of the second metal layer.

11. The assembly of claim 10, wherein the second surface of the second metal layer comprises radial grooves, and wherein the fan is mounted such that the fan blows air perpendicular to the second surface of the second metal layer.

12. The assembly of claim 9, wherein the second surface of the second metal layer comprises parallel grooves, and wherein the fan is mounted such that the fan blows air parallel to parallel grooves.

13. The assembly of claim 9, further comprising:
a heatsink mounted to the metal core printed circuit board to dissipate thermal energy from the second surface of the second metal layer; and
thermal paste between the heatsink and the second surface of the second metal layer.

14. The assembly of claim 9, wherein the one or more circuit components comprise one or more light emitting diode chips.

15. The assembly of claim 9, wherein the assembly comprises a light fixture.

16. The assembly of claim 9, further comprising:
a water-cooling system configured to pump water over the second surface of the second metal layer.

17. The assembly of claim 9, wherein the second surface of the second metal layer is etched.

18. A light emitting diode device, comprising:
a light emitting diode chip;
a metal core printed circuit board on which the light emitting diode chip is mounted on a top surface thereof, wherein a bottom surface of the metal core printed circuit board is textured with one or more of grooves or etching; and
a housing, mounted to the metal core printed circuit board, and at least partially covering the top surface of the metal core printed circuit board, wherein the housing does not cover the bottom surface of the metal core printed circuit board.

19. The light emitting diode device of claim 18, wherein the metal core printed circuit board comprises grooves of at least one of a radial pattern, a parallel groove pattern, a cross-hatch pattern, or a spiral pattern.

20. The light emitting diode device claim 18, wherein the metal core printed circuit board is textured with grooves and etching.
